(19) United States
(12) Patent Application Publication
(10) Pub. No.: US 2025/0324650 A1
(43) Pub. Date: Oct. 16, 2025

(54) Asymmetric MOSFET Devices with Optimized Spacer Thickness

(71) Applicant: pSemi Corporation, San Diego, CA (US)

(72) Inventors: Dheeraj Mohata, San Diego, CA (US); Sonja Nedeljkovic, Windsor, CO (US); Anil Kumar, San Diego, CA (US); Nijita Namboothiri Kesavan, San Diego, CA (US); Andres Zarate, San Diego, CA (US); Panglijen Candra, San Diego, CA (US)

(21) Appl. No.: 18/634,627

(22) Filed: Apr. 12, 2024

(51) Int. Cl. H01L 29/78; H01L 21/265; H01L 29/66

(52) U.S. Cl. CPC H10D 30/603; H01L 21/26513; H01L 21/26586; H10D 30/022; H10D 64/021

(57) ABSTRACT

Device structures and related fabrication methods for asymmetric MOSFETs that exhibit high BV_{DSS} and low HCl characteristics while substantially improving the poor sub-threshold slope and output resistance R_{OUT} characteristics common to conventional asymmetric MOSFET devices. Embodiments are fabricated by implanting halo and/or LDD dopants on the source-side of an asymmetric MOSFET using at least two different non-90° twist angles, each in a different quadrant. By implanting dopant at different twist angles, dopant is implanted within otherwise shadowed corners, thus essentially eliminating the parasitic transistors within such corners. Optionally, an extra implantation of halo/LDD dopants may be performed at a 90° twist angle. As a result, a non-90°, multi-twist implanted asymmetric MOSFET exhibits improved linearity and an essentially equivalent gain characteristic compared to conventional asymmetric MOSFETs. Optionally, thick spacers may be used. The asymmetric MOSFETs are quite suitable for applications, such as power amplifiers, which require good linearity and gain characteristics.

### BACKGROUND

### (1) Technical Field

This invention relates to electronic integrated circuit (IC) devices, and more particularly to metal-oxide-semiconductor field-effect transistor (MOSFET) devices.

### (2) Background

Virtually all modern electronic products—including laptop computers, mobile telephones, and electric cars—utilize metal oxide-semiconductor field-effect transistor (MOSFET) integrated circuits (ICs), and in many cases MOSFET ICs fabricated using a semiconductor-on-insulator (SOI) process, such as silicon-on-insulator, or germanium-on-insulator, or silicon/germanium-on-insulator (e.g., a SiGe alloy or a layer of Ge on a layer of Si formed on an insulator).

FIG. 1A is a stylized top plan view of a prior art IC structure 100 for a single symmetrical N-type MOSFET device. A source S, a gate structure G, and a drain D overlay an active region of N+ material 102 in this example (note that contacts to the source S, the gate structure G, and the drain D have been omitted to reduce clutter). Also shown in FIG. 1A is the top side of a body tie region 101 which, in the illustrated example, comprises a P+ region connected to the gate structure G by a polysilicon central gate tab 103 (note that the electrical contact to the body tie regions 101 is omitted for clarity).

FIG. 1B is a stylized cross-sectional view along line X-X of FIG. 1A. The IC structure 100 includes the active region 102, an insulating buried-oxide (BOX) layer 104, and a substrate 106 (note that the dimensions for the elements of the IC structure 100 are not to scale; some dimensions have been exaggerated for clarity or emphasis). The substrate 106 is typically a semiconductor material such as silicon or high-resistivity silicon. The BOX layer 104 is a dielectric, and is often SiO₂ formed as a “top” surface of the silicon substrate 106. FIG. 1B also shows the source S 108 and the drain D 110 within the active region 102, surrounded by shallow trench isolation (STI) structures 114, with the gate structure G 112 situated on the upper surface of the active region 102.

For some applications, the BOX layer 104 may be omitted, such as in bulk silicon MOSFET designs. For some applications, one or more additional layers or regions may be included, such as a trap-rich layer or the like between the substrate 106 and the BOX layer 104. In some embodiments, a laterally-extended drain may be included.

The illustrated gate structure G 112 includes a conductive layer 120, such as polysilicon or metal, atop an insulating gate oxide (GOX) layer 122. In the illustrated example, the gate structure G 112 is surrounded by dielectric spacers 124. A “P well” or body 126 is defined within the active region 102 situated below the gate structure G 112 and between the source S 108 and the drain D 110. In operation, a “conduction channel” (for an enhancement mode MOSFET) or an “inversion channel” (for a depletion mode MOSFET) is generated within the body 126 between the source S 108 and the drain D 110 and generally proximate to the GOX layer 122 (e.g., within about the top 100A of the body 126). A P-type MOSFET device has a similar structure, but with opposite polarities for the dopants.

The BOX layer 104 and the active region 102 (which may include one or more MOSFETs) may be collectively referred to as a “device region” or “substructure” 128 for convenience (noting that other structures or regions may intrude into the substructure 128 in particular IC designs). A superstructure (not shown) of various elements, regions, and structures may be fabricated in known fashion on or above the substructure 128 in order to implement particular functionality. The superstructure may include, for example, conductive interconnections from the illustrated MOSFET to other components (including other MOSFETs) and/or external contacts, passivation layers and regions, and protective coatings.

Well-known improvements to the maximum voltage handling capability of a MOSFET have included use of halo implants and lightly-doped drain (LDD) regions. A halo implant mitigates punch-through while an LDD region mitigates avalanche breakdown. Referring again to the N-type MOSFET example shown FIG. 1B, halo implants 130 are pocket regions implanted with a P type material (which may be P+ type material) that increases a sub-surface electric field to reduce so-called punch-through, or short channel, conduction between the source S and the drain D, thus increasing breakdown voltage. LDD regions 132 are lightly-doped with N type material to extend the source S and drain D underneath the gate G. The LDD regions 132 reduce high electric fields caused by a voltage applied at the drain D, thereby increasing the drain-channel breakdown voltage.

Halo implants and LDD regions are generally formed at a particular stage of symmetrical MOSFET fabrication after formation of the gate structure 112 by vertical (particularly for LDD regions) and/or angled implantation (particularly for halo implants) of a suitable dopant. In FIG. 1B, halo implants 130 and LDD regions 132 have been symmetrically formed within the source S and the drain D on both sides of the gate structure 112.

In some applications, such as power amplifiers, it has been found useful to create “asymmetric” MOSFETs which exhibit a higher breakdown voltage BV_{DSS} and reduced hot carrier injection (HCl) issues compared to a symmetric MOSFETs such as is shown in FIG. 1B. HCl is a phenomenon where a charge carrier (electron or hole) gains sufficient kinetic energy to overcome a potential barrier necessary to break an interface state. The charge carriers can become trapped in the gate dielectric of a MOSFET and may permanently change the switching characteristics of the transistor. HCl is one of the mechanisms that adversely affects the reliability of MOSFETs.

FIG. 1C is a stylized cross-sectional view of an asymmetric MOSFET 150. In contrast to conventional vertical halo/LDD dopant implantation, such dopants may be generally implanted at two angles. For example, a first half of an LDD dose may be implanted vertically and a second half may be implanted at a “tilt” angle θ with respect to a vertical line perpendicular to the top surface of a MOSFET device 150. This double-angle approach provides a trade-off between smaller access resistance and increased HCl effects (from an LDD perspective). The values of θ typically differ for halo implants versus LDD region implants—for example, the tilt angle θ may be about 30° for halo implants, and about 10° for LDD implants. In the illustrated example, tilted implantation of dopants for halo implants 130 and LDD regions 132 is made only from the source S side of the MOSFET 150, such that the gate structure 112 “shadows” the drain D side implant. Accordingly, the halo implants 130 and LDD regions 132 on the source S side extend further underneath the gate structure 112 compared to the halo implants 130 and LDD regions 132 on the drain D side. The resulting asymmetrical implants on the drain D side relative to the source S side improves BV_{DSS} and reduces HCl events due to the graded junction on the drain side D.

Despite the BV_{DSS} and HCl advantages of conventional asymmetric MOSFET devices for power applications, there is still a need for improved performance in such devices. The present invention addresses that need.

### SUMMARY

The present invention encompasses device structures and related fabrication methods for asymmetric MOSFETs that exhibit high BV_{DSS} and low HCl characteristics while substantially improving the poor sub-threshold slope and output resistance R_{OUT} characteristics common to conventional asymmetric MOSFET devices.

Some embodiments are fabricated by implanting halo and/or LDD dopants only from the source-side of an asymmetric MOSFET using at least two different non-90° twist angles, each in a different quadrant. By implanting dopant at different twist angles, dopant is implanted within otherwise shadowed corners, thus essentially eliminating the parasitic transistors within such corners. Optionally, an extra implantation of halo/LDD dopants may be performed at a 90° twist angle. As a result, a non-90°, multi-twist implanted asymmetric MOSFET exhibits improved linearity and an essentially equivalent gain characteristic compared to conventional asymmetric MOSFETs. The novel asymmetric MOSFETs are quite suitable for applications, such as power amplifiers, which require good linearity and gain characteristics.

Even further improvements to the MOSFET device parameters such as transconductances (gₘ and g_{ds}) and parasitic capacitances (e.g., C_{GD}, C_{GS}) and their derivatives may be obtained by optimizing the thickness of the gate structure spacers before implanting halo and/or LDD dopants. At the same time, the BV_{DSS} and reliability of an asymmetric MOSFET can be improved without a significant sacrifice in gain. For example, some embodiments include an asymmetric MOSFET including a gate structure overlying a body region, the gate structure including a conductive layer and having a first side and a second side, a first implant region asymmetrically implanted with a dopant only from the first side of the gate structure, the first implant region located on the first side of the gate structure and not extending to any significant extent into the body region beneath a first lateral edge of the conductive layer on the first side of the gate structure edge, and a second implant region asymmetrically implanted with the dopant only from the first side of the gate structure, the second implant region located on the second side of the gate structure and not extending to any significant extent into the body region beneath a second lateral edge of the conductive layer on the second side of the gate structure edge.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1A is a stylized top plan view of a prior art IC structure for a single N-type MOSFET device.

FIG. 1B is a stylized cross-sectional view along line X-X of FIG. 1A.

FIG. 1C is a stylized cross-sectional view of an asymmetric MOSFET.

FIG. 2A is a top plan view of a first conventional asymmetric N-type MOSFET that has been asymmetrically implanted with dopants for halo implants and LDD regions.

FIG. 2B is a stylized cross-sectional view along line X-X of FIG. 2A.

FIG. 2C is a graph of drain current I_{D} versus gate voltage V_{G} for a conventional asymmetric N-type MOSFET device.

FIG. 2D is a top plan view of a second conventional asymmetric N-type MOSFET that has been asymmetrically implanted with dopants for halo implants and LDD regions.

FIG. 3A is a top plan view of a first asymmetric N-type MOSFET in accordance with the present invention.

FIG. 3B is a top plan view of a second asymmetric N-type MOSFET in accordance with the present invention.

FIG. 4 is a graph of MOSFET drain current I_{D} versus gate voltage V_{G} for a conventional 90°-implanted asymmetric MOSFET and a non-90°, dual-twist implanted asymmetric MOSFET fabricated in accordance with the teachings of the present invention.

FIG. 5 is a graph of MOSFET drain current I_{D} versus drain-source voltage V_{DS} at a selected gate voltage V_{G} for a conventional 90°-implanted asymmetric MOSFET and a non-90°, dual-twist implanted asymmetric MOSFET fabricated in accordance with the teachings of the present invention.

FIG. 6 is a graph of MOSFET gain gₘ versus gate voltage V_{G} for a conventional 90° implanted asymmetric MOSFET and a non-90°, dual-twist implanted asymmetric MOSFET fabricated in accordance with the teachings of the present invention.

FIG. 7 is a graph of continuous wave (CW) error-vector magnitude (EVM) versus CW modulated output poser P_{OUT} for a conventional 90° implanted asymmetric MOSFET and a non-90°, dual-twist implanted asymmetric MOSFET.

FIG. 8 is a stylized cross-sectional view of a portion of a prior art asymmetric MOSFET 800, focusing on the gate structure 802 and underlying active layer 102.

FIG. 9 is a stylized cross-sectional view of a portion of an asymmetric MOSFET in accordance with the present invention, focusing on the gate structure and underlying active layer.

FIG. 10A is a double graph of Idrain (expressed as device drain current density) versus gate voltage Vgate and gₘ (expressed as transconductance density) versus Vgate for modeled asymmetric MOSFET devices having differing spacer thicknesses.

FIG. 10B is a double graph of Idrain versus drain-to-source voltage Vdrain and drain-to-source transconductance g_{ds} versus Vdrain for modeled asymmetric MOSFET devices having differing spacer thicknesses.

FIG. 10C is a double graph of capacitance (expressed as farad density) versus Vgate for modeled asymmetric MOSFET devices having differing spacer thicknesses.

FIG. 10D is a graph of Idrain versus Vdrain for modeled asymmetric MOSFET devices having differing spacer thicknesses, with Vdrain sufficient to exceed BV_{DSS} for each device.

FIG. 10E is a graph of error vector magnitude (EVM) versus Pout for modeled asymmetric MOSFET devices having differing spacer thicknesses.

FIGS. 11A-11D are cross-sectional stylized views of example fabrication stages for the novel asymmetric MOSFET of FIG. 9.

FIG. 12 is a top plan view of a substrate that may be, for example, a printed circuit board or chip module substrate (e.g., a thin-film tile).

FIG. 13 is a process flow chart showing one method for making an asymmetric MOSFET.

FIG. 14 is a process flow chart showing one method for making an asymmetric MOSFET in and on an active region of an integrated circuit.

FIG. 15 is a process flow chart showing one method for making an asymmetric MOSFET having a gate structure overlying a body region, the gate structure including a conductive layer and having a first side and a second side.

FIG. 16 is a process flow chart showing one method for making an asymmetric MOSFET in and on an active region of an integrated circuit.

Like reference numbers and designations in the various drawings indicate like elements unless the context requires otherwise.

### DETAILED DESCRIPTION

The present invention encompasses device structures and related fabrication methods for asymmetric MOSFETs that exhibit high BV_{DSS} and low HCl characteristics while substantially improving the poor sub-threshold slope and output resistance R_{OUT} characteristics common to conventional asymmetric MOSFET devices.

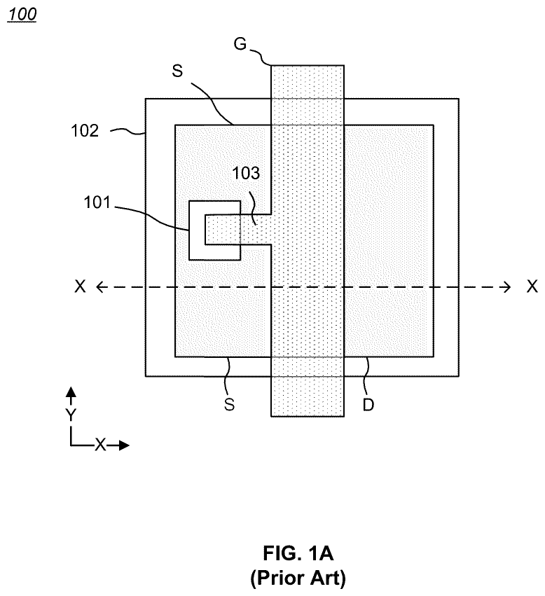

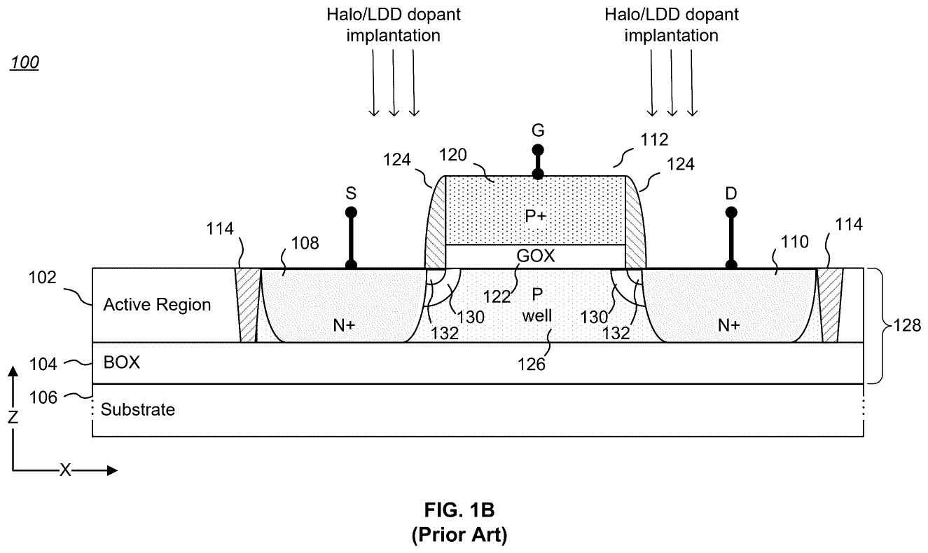

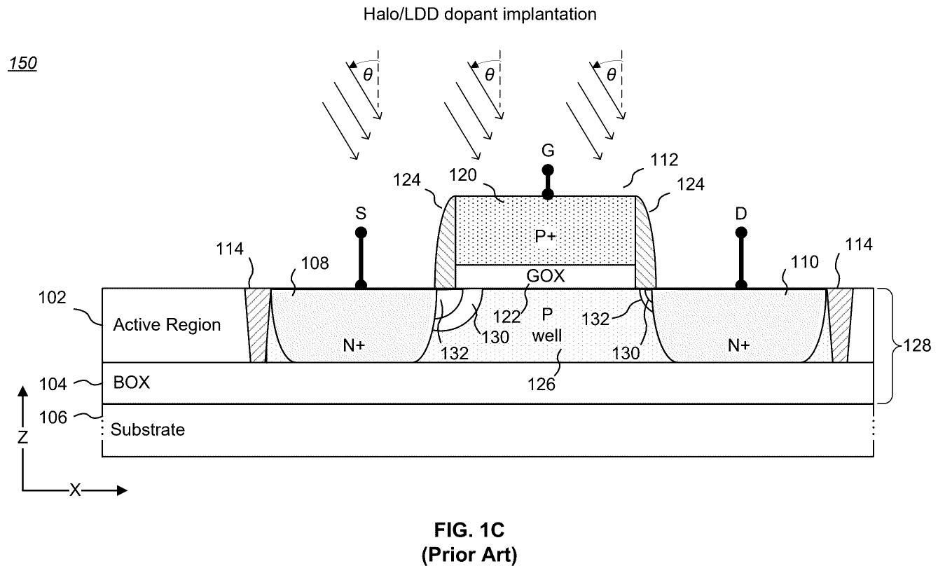

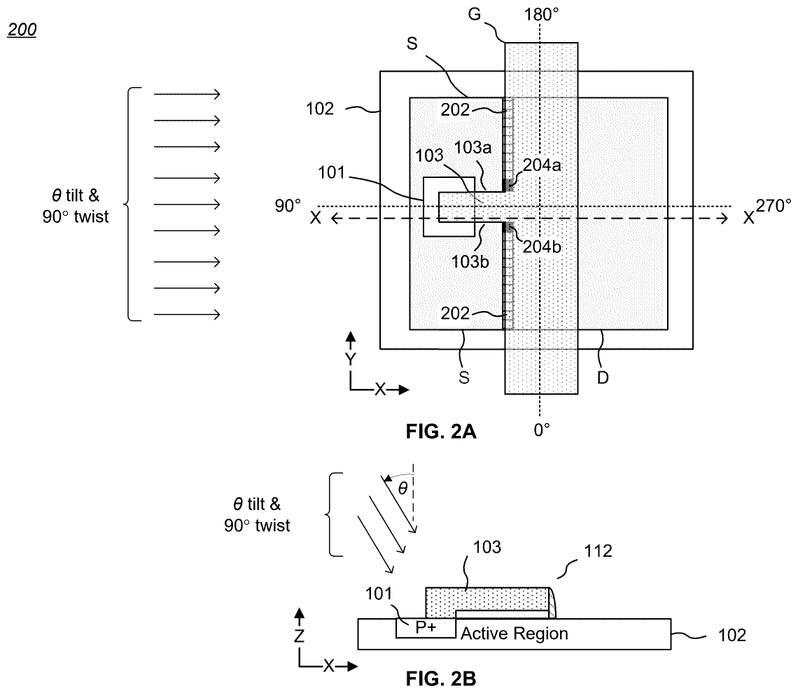

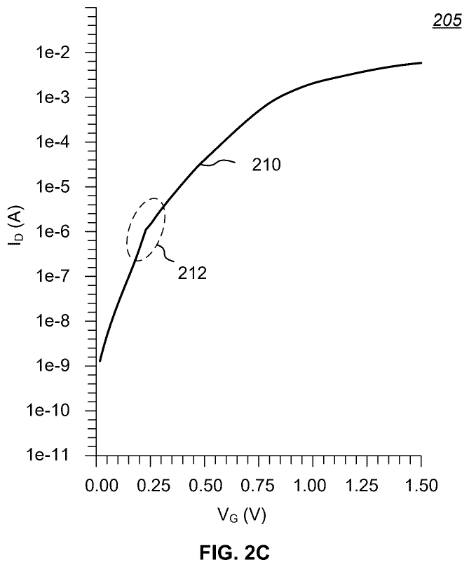

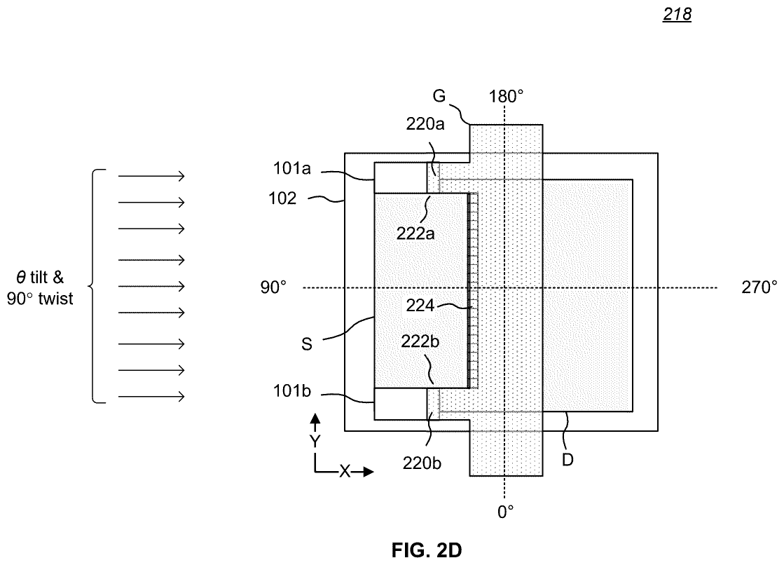

Conventional asymmetric N-type MOSFET devices suffer from poor sub-threshold slope and R_{OUT} due to the non-uniform halo implantation around the source-side central gate tab 103 (see FIG. 1A). For example, FIG. 2A is a top plan view of a first conventional asymmetric N-type MOSFET 200 that has been asymmetrically implanted with dopants for halo implants 130 and LDD regions 132. FIG. 2B is a stylized cross-sectional view along line X-X of FIG. 2A. In the illustrated example, the halo/LDD dopants are implanted only from the source S side of the gate structure G, with a tilt angle of θ relative to the Z dimension of the gate structure G (noting that θ may differ for halo implants versus LDD region implants) and a twist angle of 90° relative to the Y dimension of the gate structure G.

Because of shadowing by the body tie region 101 and the parallel orientation of the sides 103a, 103b of the central gate tab 103 with respect to the twist angle, the sides 103a, 103b of the central gate tab 103 receive a lower amount of implanted dopant compared to the source-side edge 202 of the gate structure G. In particular, the corners 204a, 204b formed by the sides 103a, 103b and source-side edge 202 of the gate structure G have reduced concentrations of dopant. The lower dopant concentration results in a lower threshold voltage V_{TH} for the corners 204a, 204b of the gate structure G. As a result, the corners 204a, 204b turn ON earlier than the rest of the transistor, causing the sub-threshold slope of I_{OFF} of the device to degrade. For example, FIG. 2C is a graph 205 of drain current I_{D} versus gate voltage V_{G} for a conventional asymmetric N-type MOSFET device. The low-dopant, low V_{TH} corners 204a, 204b of the gate structure G result in a tiny parasitic transistor at each of those corners that begins conducting at a V_{G} several 10's to 100's of mV below V_{TH} (i.e., the V_{TH} of the “normal” main transistor), resulting in a “kink” or “shoulder” region (within the dashed-oval 212) of the graph line 210—consequently, the leakage of the device suffers significantly.

In addition, the unidirectional halo/LDD implantation orientation results in reduced P-type dopant implantation underneath the polysilicon central gate tab 103, thus increasing resistance for holes between the device channel and the body tie region 101, thereby increasing floating body effects and decreasing R_{OUT}.

The “low dopant region” problem of conventional asymmetric N-type MOSFET devices illustrated by FIGS. 2A and 2B occurs in other device geometries. For example, FIG. 2D is a top plan view of a second conventional asymmetric N-type MOSFET 218 that has been asymmetrically implanted with dopants for halo implants 130 and LDD regions 132. In the illustrated example, the single central gate tab 103 of FIG. 2A has been replaced by two polysilicon edge gate tabs 220a, 220b located near the Y-dimension ends of the gate structure G. The polysilicon edge gate tabs 220a, 220b overlay corresponding body tie regions 101a, 101b. Implantation of halo/LDD dopants with a tilt angle of θ (e.g., about 30° for halo implants and about 10° for LDD implants) and a twist angle of 90° results in the sides 222a, 222b of the edge gate tabs 220a, 220b receiving a lower amount of implanted dopant compared to the source-side edge 224 of the gate structure G.

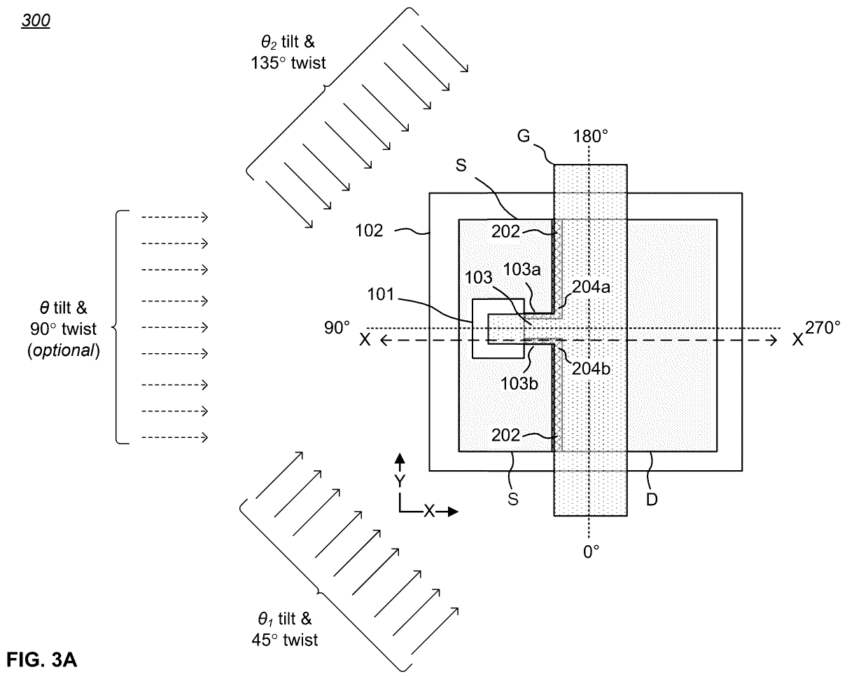

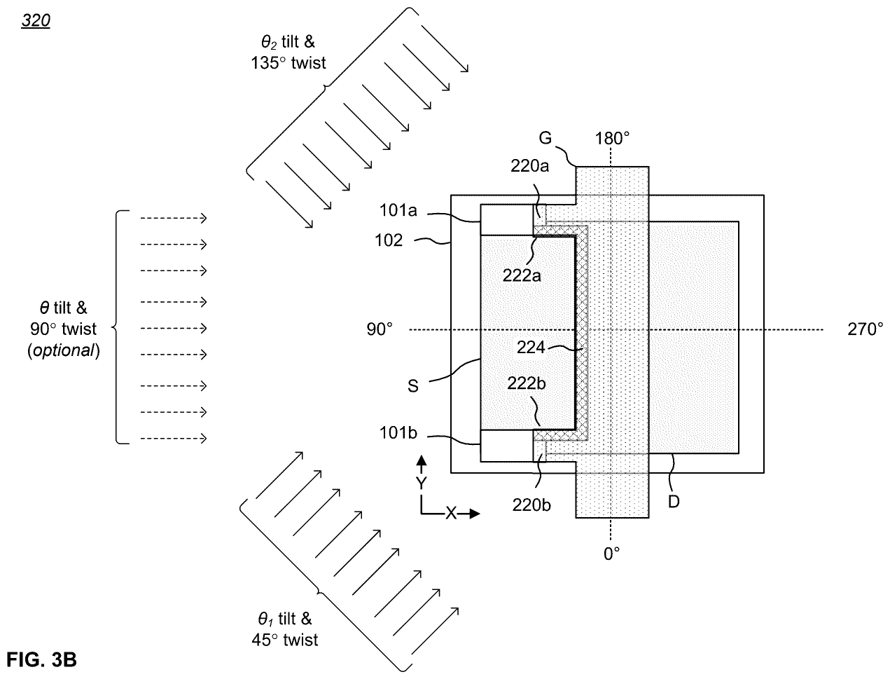

The inventors found that instead of implanting halo/LDD dopants on the source-side of an asymmetric MOSFET at a conventional 90° twist angle (i.e., perpendicular to the Y dimension of the gate structure G), an asymmetric MOSFET with improved performance can be fabricated by implanting halo/LDD dopants at least two different non-90° twist angles, each in different quadrants (e.g., 0°-90° and 90°-180°). For example, FIG. 3A is a top plan view of a first asymmetric N-type MOSFET 300 in accordance with the present invention. The example MOSFET 300 is of the type having a single central gate tab 103. The MOSFET 300 is asymmetrically implanted with dopants for halo regions and/or LDD regions by positioning the MOSFET 300 with respect to an implant source (e.g., a conventional ion implantation device, not shown) at a first twist angle in a first range of from about 0° to about 89° and at a second twist angle in a second range of from about 91° to about 180° with respect to the long axis (0°-180°) of the gate structure. Preferred first and second ranges are 35°-55° and 125°-145°, respectively. As a practical matter in terms of equipment setup, the first twist angle may be set at 45° and the second twist angle may be set at 135°, as illustrated in FIG. 3A.

Implantation at two or more twist angles may be performed sequentially (either order works), or concurrently if the implantation system provides two or more implant sources that may be set to suitable non-90° twist angles. Note that, optionally, an extra implantation of halo/LDD dopants may be performed at a 90° twist angle. In some embodiments, the tilt angle may differ for each twist angle (which need not be the same), and accordingly the concentration of dopant at each of the twist angles may need to be appropriately adjusted so that the V_{TH} value achieved for the parasitic corner transistors is equal to or greater than the V_{TH} value of the main transistor channel.

As should be apparent from the relative positions of the MOSFET 300 and the two different non-90° twist angles, the body tie region 101 will not shadow the corners 204a, 204b formed by the sides 103a, 103b and source-side edge 202 of the gate structure G. Accordingly, dopant will be implanted within the corners 204a, 204b, thus essentially eliminating the parasitic transistors described above with respect to FIG. 2B. As a result, the direct current (DC) and radio frequency (RF) characteristics of the MOSFET 300 are expected to improve. In particular, the RF linearity of the MOSFET 300 is improved.

The inventive technique may be used for other device geometries. For example, FIG. 3B is a top plan view of a second asymmetric N-type MOSFET 320 in accordance with the present invention. The illustrated example includes two polysilicon edge gate tabs 220a, 220b. Implantation of halo/LDD dopants at two different non-90° twist angles in different respective quadrants ensures that the sides 222a, 222b of the edge gate tabs 220a, 220b receive a suitable amount of implanted dopant to essentially eliminate the parasitic transistors described above with respect to FIG. 2D.

As should be clear, while the illustrated examples show only two different non-90° twist angles in different respective quadrants, more than two non-90° twist angles may be used to fabricate an asymmetric MOSFET. In addition, more than one tilt angle θ may be used to implant dopant into the halo and/or LDD regions. Further, while the examples have focused on N-type MOSFETs, the same techniques may be used to fabricate P-type MOSFETs.

Ideally, power MOSFETs should not appreciably alter or affect an RF signal. However, the solid-state nature of an IC causes undesirable interactions between regions of the IC, leading to such phenomena as leakage currents and parasitic capacitances, inductances, and resistances. Accordingly, MOSFETs generally behave less than ideally. Fortunately, small improvements in MOSFET structure and fabrication processes can result in significant performance improvements.

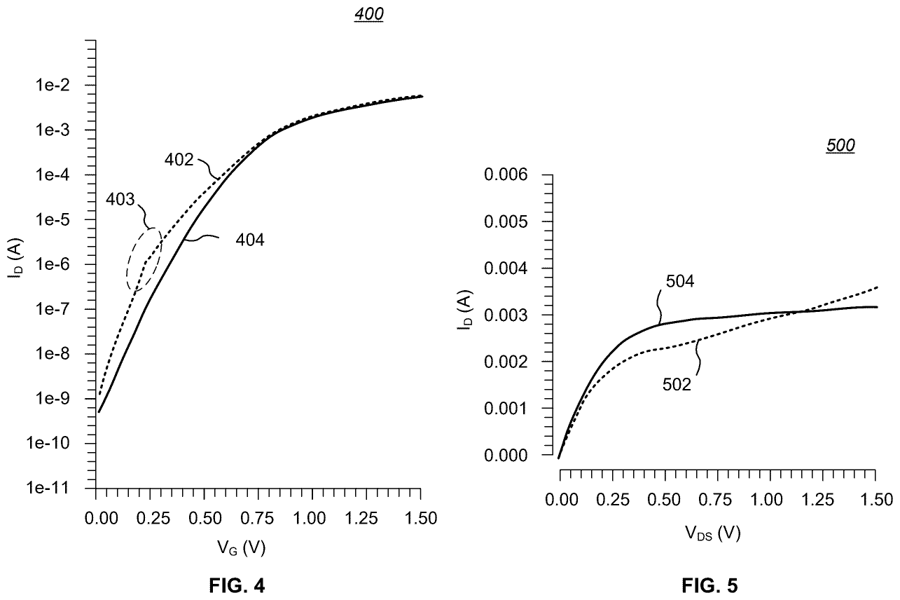

For example, FIG. 4 is a graph 400 of MOSFET drain current I_{D} versus gate voltage V_{G} for a conventional 90°-implanted asymmetric MOSFET (graph line 402) and a non-90°, dual-twist implanted asymmetric MOSFET (graph line 404) fabricated in accordance with the teachings of the present invention. Graph line 402 exhibits a shoulder region (within the dashed-oval 403) attributable to the low-dopant, low V_{TH} corners 204a, 204b of the gate structure G (see FIG. 2A) of the conventional asymmetric MOSFET, like the graph line 210 in FIG. 2C. In contrast, graph line 404 exhibits a smoother, more linear increase in I_{D} as a function of V_{G}.

FIG. 5 is a graph 500 of MOSFET drain current I_{D} versus drain-source voltage V_{DS} at a selected gate voltage V_{G} for a conventional 90°-implanted asymmetric MOSFET (graph line 502) and a non-90°, dual-twist implanted asymmetric MOSFET (graph line 504) fabricated in accordance with the teachings of the present invention. In a conventional asymmetric MOSFET, the body tie polysilicon gate extension (central gate tab 103 in FIG. 3A, edge gate tabs 220a, 220b in FIG. 3B) poses a relatively high resistance path for holes to be collected by the P+ body tie regions 101, 101a, 101b, thus increasing floating body effects and degrading device linearity, as shown by graph line 502. For a MOSFET configuration like that shown in FIG. 3A, the extra coverage of implanted halo dopant along the sides 103a, 103b of the central gate tab 103 provides a low resistance path for holes to travel to the body-to-source tie of the device. Similarly, for a MOSFET configuration like that shown in FIG. 3B, the extra coverage of implanted halo dopant along the sides 222a, 222b of the edge gate tabs 220a, 220b provides a low resistance path for holes to travel to the body-to-source tie of the device. The result is that asymmetric MOSFETs in accordance with the present invention exhibit very good linearity, as shown by graph line 504.

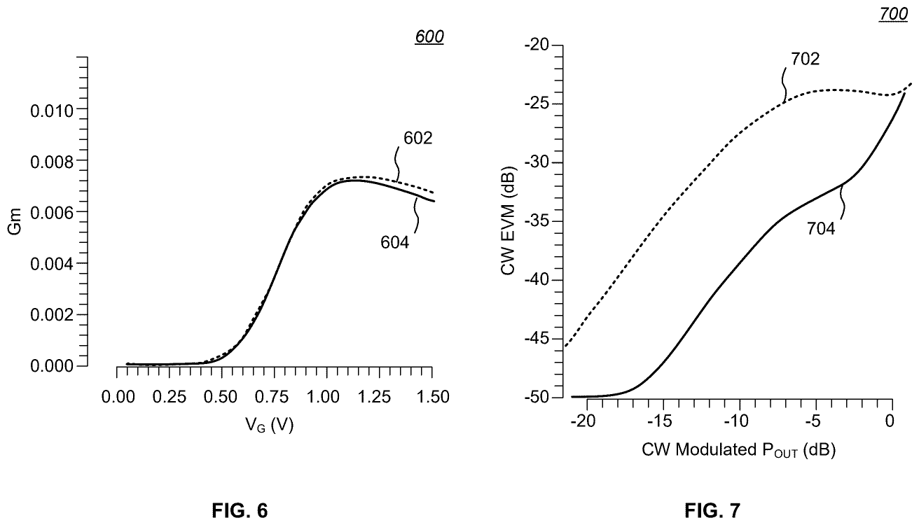

FIG. 6 is a graph 600 of MOSFET transconductance gₘ versus gate voltage V_{G} for a conventional 90° implanted asymmetric MOSFET (graph line 602) and a non-90°, dual-twist implanted asymmetric MOSFET (graph line 604) fabricated in accordance with the teachings of the present invention. The very close overlap of the graph lines 602, 604 indicate that MOSFETs fabricated in accordance with the teachings of this disclosure exhibit no significant reduction in gain compared to a conventional design.

FIG. 7 is a graph 700 of continuous wave (CW) error-vector magnitude (EVM) versus CW modulated output power P_{OUT} for a conventional 90° implanted asymmetric MOSFET (graph line 702) and a non-90°, dual-twist implanted asymmetric MOSFET (graph line 704). As the graph lines indicate, embodiments of the present invention exhibit better EVM performance at higher output powers.

Consequently, compared to a conventional 90°-implanted asymmetric MOSFET, a non-90°, multi-twist implanted asymmetric MOSFET exhibits improved sub-threshold slope and output resistance R_{OUT} characteristics which result in improved linearity and an essentially equivalent gain characteristic. Furthermore, non-90°, multi-twist implanted asymmetric MOSFETs exhibit high BV_{DSS} and low HCl characteristics, making them quite suitable for applications, such as power amplifiers, that also require good linearity and gain characteristics.

In some applications, such as power amplifiers (PAs), certain device parameters of an asymmetric MOSFET device (such as transconductance gₘ, output conductance g_{ds} and parasitic capacitances C_{GD} and C_{GS}) show more bias dependence than in symmetric MOSFET devices, which is detrimental to the linearity of a PA. For a PA, gain is primarily dependent on the gₘ transconductance, AMAM distortion (instantaneous gain versus signal power characteristic) primarily depends on the gₘ transconductance, the gate-to-source parasitic capacitance C_{GS}, and their respective derivatives, while AMPM distortion (instantaneous phase distortion versus signal power characteristic) primarily depends on feedback capacitances such as the gate-to-drain parasitic capacitance C_{GD} and their derivatives. The transconductance and output conductances of a MOSFET are key variables which present how sensitively the drain current changes in proportion to changes in the gate and drain voltages in saturation mode, respectively. The parasitic capacitances C_{GD} and C_{GS} are important parameters affecting switching performance—lower values are better. All of these parameters are affected by the amount and proximity of asymmetric halo and LDD implantation with respect to the device gate structure G. Contributing factors affecting the amount and proximity of asymmetric halo and LDD implantation include the tilt and twist angles of implantation and the height of the shadowing structures. Balancing all of these factors during fabrication to achieve a set of device specifications can be challenging.

The inventors have realized that an additional controllable factor exists during MOSFET fabrication: the thickness (in the X dimension) of the first spacer around the gate structure of an asymmetric MOSFET device. More specifically, improvements to MOSFET device parameters such as transconductances (gₘ and g_{ds}) and parasitic capacitances (e.g., C_{GD}, C_{GS}) and their derivatives may be obtained by optimizing the thickness of the gate structure spacers before implanting halo and/or LDD dopants. At the same time, the BV_{DSS} and reliability of an asymmetric MOSFET can be improved without a significant sacrifice in gain, allowing use of such devices at relatively higher V_{DD} values.

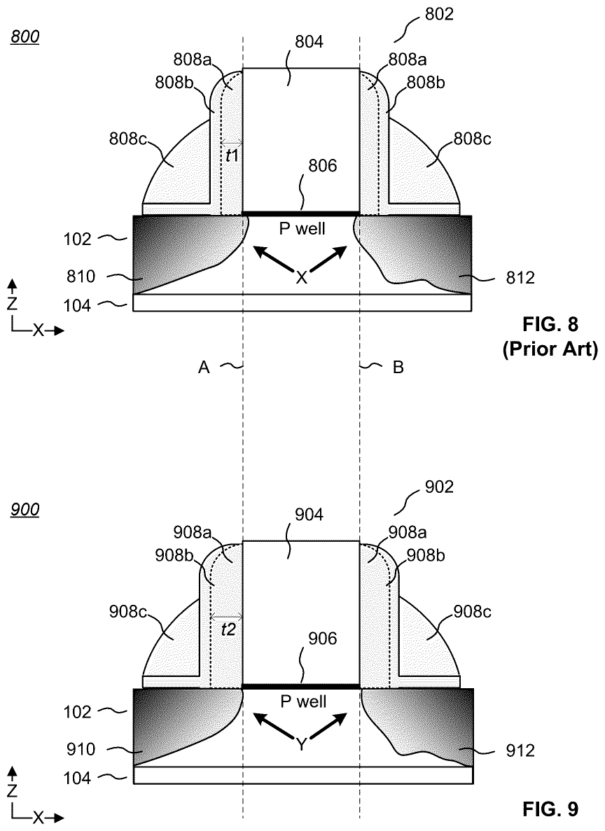

FIG. 8 is a stylized cross-sectional view of a portion of a prior art asymmetric MOSFET 800, focusing on the gate structure 802 and underlying active layer 102. The substrate 106 shown in FIG. 1C has been omitted. The illustrated gate structure 802 includes a conductive layer 804, such as polysilicon or metal, atop an insulating gate oxide (GOX) layer 806. In the illustrated example, the gate structure 802 is bracketed by a set of dielectric spacers 808a-808c. A first dielectric spacer 808a having a thickness (in the X dimension) of t1 (e.g., 130A) may be formed by deposition of a spacer material (e.g., SiO₂) and etching the deposited material to conform to the lateral sides of the gate structure 802. Second and third dielectric spacers 808b (e.g., 60A in the X dimension) and 808c (e.g., 450A in the X dimension) may be formed by plasma enhanced deposition of a bi-layer spacer stack, where the second dielectric spacer material 808b is typically SiO₂ and the third dielectric spacer material 808c is typically SiN followed by etching of the third dielectric spacer 808c.

A source-side implant region 810 is shown with gradient shading to indicate halo and/or LDD dopant implants. Similarly, a drain-side implant region 812 is shown with gradient shading to indicate halo and/or LDD dopant implants. Using the asymmetric implantation processes described above, dopants are introduced into the active layer 102 only from the source side of the gate structure 802 using selected tilt and twist angles. Accordingly, due to the single-sided direction of implantation and shadowing effects as described above, the source-side implant region 810 differs in shape from the drain-side implant region 812. This asymmetry results in some of the beneficial characteristics of an asymmetric MOSFET device.

FIG. 9 is a stylized cross-sectional view of a portion of an asymmetric MOSFET 900 in accordance with the present invention, focusing on the gate structure 902 and underlying active layer 102. The substrate 106 shown in FIG. 1C has been omitted. The illustrated gate structure 902 includes a conductive layer 904, such as polysilicon or metal, atop an insulating gate oxide (GOX) layer 906. In the illustrated example, the gate structure 902 is bracketed by a set of dielectric spacers 908a-908c. A first dielectric spacer 908a having a thickness (in the X dimension) of t2 may be formed by deposition of a spacer material (e.g., SiO₂) and etching the deposited material to conform to the lateral sides of the gate structure 902. Second and third dielectric spacers 908b and 908c may be formed by plasma enhanced deposition of a bi-layer spacer stack, where the second dielectric spacer material 908b is typically SiO₂ and the third dielectric spacer material 908c is typically SiN, followed by etching of the third dielectric spacer 908c. Notably, t2 is greater than t1 by 20 Å or more in this example.

A source-side implant region 910 is shown with gradient shading to indicate halo and/or LDD dopant implants. Similarly, a drain-side implant region 912 is shown with gradient shading to indicate halo and/or LDD dopant implants. Using the asymmetric implantation processes described above, dopants are introduced into the active layer 102 only from the source-side of the gate structure 902 using selected tilt and twist angles. Accordingly, the source-side implant region 910 differs in shape from the drain-side implant region 912. This asymmetry results in some of the beneficial characteristics of an asymmetric MOSFET device.

Notably, the thinner spacer thickness t1 in FIG. 8 allows the source-side implant region 810 and the drain-side implant region 812 to extend into the device channel past the lateral edges of the conductive layer 804 within the gate structure 802, as indicated by dashed marker lines marker A and B (note arrows X in FIG. 8). In contrast, the greater degree of implant shadowing provide by the thicker spacer thickness t2 in FIG. 9 prevents the source-side implant region 910 and the drain-side implant region 912 from extending into the device channel beneath the lateral edges of the conductive layer 904 within the gate structure 902 to any significant extent, also as indicated by shared dashed marker lines marker A and B (note arrows Y in FIG. 9). As t2 increases, the implant region 910, 912 junction edges move further away from the lateral edges of the conductive layer 904 within the gate structure 902. Note also that the extent of implantation underneath the gate structure 902 is different on the source-side compared to the drain-side because of the halo/LDD implantation on the source-side.

The inventors have found that as little as about a 15% increase in t2 over t1 results in a significant improvement for certain critical device parameters with little change to less critical device parameters. Generally, optimizing spacer thickness in an asymmetric MOSFET can result in (1) reduced overall parasitic/fringe capacitance, especially C_{GD}, which improves AMPM distortion, (2) improved derivative values for gₘ and g_{ds}, which improves AMAM distortion, and improved ruggedness or HCl reliability due to improved BV_{DSS} values.

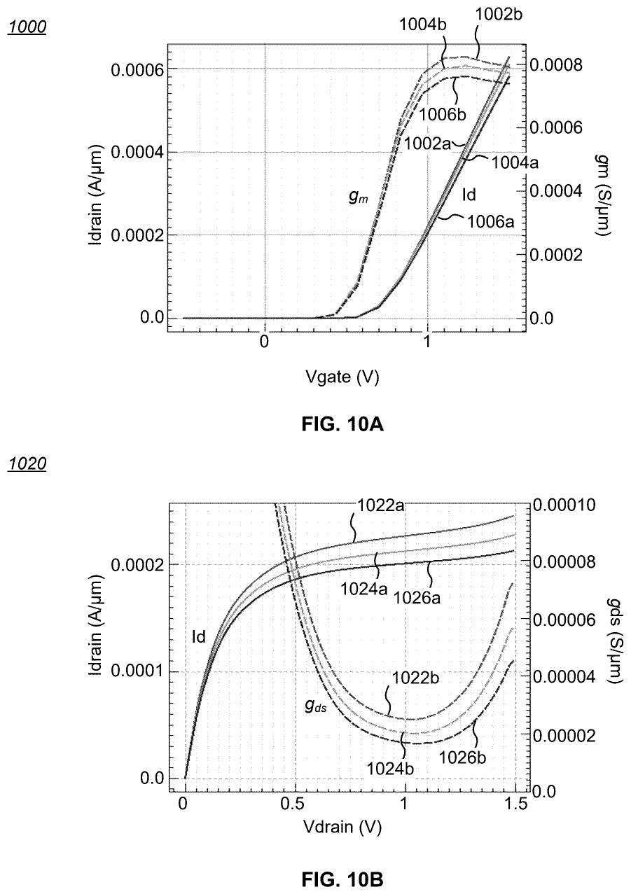

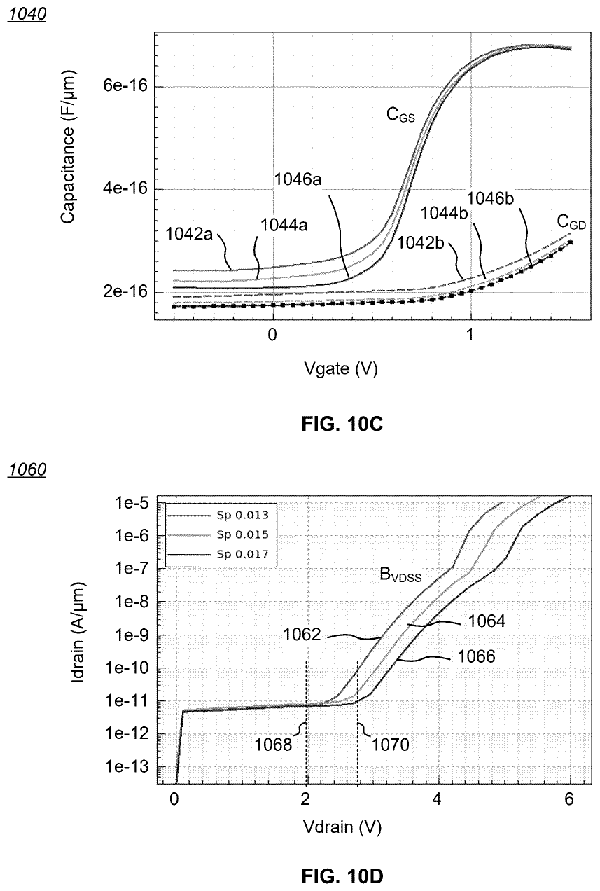

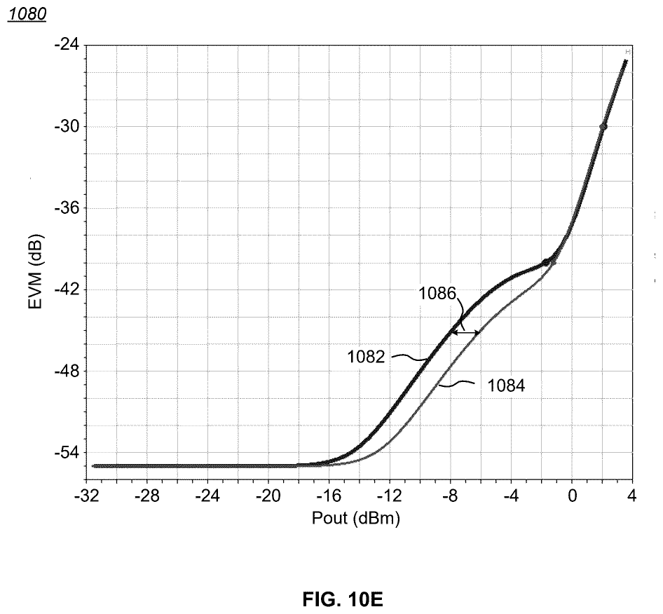

FIG. 10A is a double graph 1000 of Idrain (expressed as device drain current density) versus gate voltage Vgate and gₘ (expressed as transconductance density) versus Vgate for modeled asymmetric MOSFET devices having differing spacer thicknesses. For all models, Vdrain=1.2V. Graph lines 1002a-1006a represent Idrain (also shown as Id) versus Vgate for MOSFET devices having different t1 or t2 space thicknesses.

Graph line 1002a represents t1=13 nm spacers used by one commercial foundry. Graph line 1004a represents t2=15 nm spacers (˜15% thicker than t1). Graph line 1006a represents t2=17 nm spacers (˜31% thicker than t1).

Graph lines 1002b-1006b represent gₘ versus Vgate for MOSFET devices having different t1 or t2 space thicknesses. Graph line 1002b represents t1=13 nm spacers used by one commercial foundry. Graph line 1004b represents t2=15 nm spacers. Graph line 1006b represents t2=17 nm spacers.

Notably, increasing the thickness of the spacers in accordance with the present invention results in little impact on the performance parameters illustrated in double graph 1000; in particular, Idrain after saturation (Vgate≥˜1V) does not change much.

FIG. 10B is a double graph 1020 of Idrain versus drain-to-source voltage Vdrain and drain-to-source transconductance g_{ds} versus Vdrain for modeled asymmetric MOSFET devices having differing spacer thicknesses. For all models, Vgate=1.0V.

Graph lines 1022a-1026a represent Idrain versus Vdrain for MOSFET devices having different t1 or t2 space thicknesses. Graph line 1022a represents t1=13 nm spacers used by one commercial foundry. Graph line 1024a represents t2=15 nm spacers. Graph line 1026a represents t2=17 nm spacers.

Graph lines 1022b-1026b represent gₘ versus Vgate for MOSFET devices having different t1 or t2 space thicknesses. Graph line 1022b represents t1=13 nm spacers used by one commercial foundry. Graph line 1024b represents t2=15 nm spacers. Graph line 1026b represents t2=17 nm spacers, graph line 1026b.

Notably, g_{ds} improves significantly (lower is better) as spacer thickness t2 increases relative to t1.

FIG. 10C is a double graph 1040 of capacitance (expressed as farad density) versus Vgate for modeled asymmetric MOSFET devices having differing spacer thicknesses. For all models, Vdrain=1.1V and frequency=2 GHz.

Graph lines 1042a-1046a represent C_{GS} versus Vgate for MOSFET devices having different t1 or t2 space thicknesses. Graph line 1042a represents t1=13 nm spacers used by one commercial foundry. Graph line 1044a represents t2=15 nm spacers. Graph line 1046a represents t2=17 nm spacers.

Graph lines 1042b-1046b represent C_{GD} versus Vgate for MOSFET devices having different t1 or t2 space thicknesses. Graph line 1042b represents t1=13 nm spacers used by one commercial foundry. Graph line 1044b represents t2=15 nm spacers. Graph line 1046b represents t2=17 nm spacers.

Notably, both C_{GS} and C_{GD} improve significantly (lower is better) as spacer thickness t2 increases relative to t1.

FIG. 10D is a graph 1060 of Idrain versus Vdrain for modeled asymmetric MOSFET devices having differing spacer thicknesses, with Vdrain sufficient to exceed BV_{DSS} for each device. For all models, Vgate=0V. Graph line 1062 represents Idrain versus Vdrain for MOSFET devices having t1=13 nm spacers used by one commercial foundry. Graph line 1064 represents Idrain versus Vdrain for MOSFET devices having t2=15 nm spacers. Graph line 1066 represents Idrain versus Vdrain for MOSFET devices having t2=17 nm spacers. Notably, dotted lines 1068 and 1070 shows that the BV_{DSS} for a device having t2=17 nm spacers is about 0.6V greater than the BV_{DSS} for a device having t1=13 nm spacers, which is significant. Stated another way, at the BV_{DSS} for a MOSFET device having a 17 nm t2 thickness for the first dielectric spacer 908a (see FIG. 9), a MOSFET device having a 13 nm t1 thickness for the first dielectric spacer 808a (see FIG. 8) is leaking an order of magnitude more current.

FIG. 10E is a graph 1080 of error vector magnitude (EVM) versus Pout for modeled asymmetric MOSFET devices having differing spacer thicknesses. In this example, V_{DS}=1.1V, I_{DS}=4 mA (33 μA/μm), frequency=5.5 GHz, and the system impedance Zₛ=50 Ohms. Graph line 1082 represents a device having t1=13 nm spacers, while graph line 1084 represents a device having t2=17 nm spacers. At an EVM of −45 (see arrow 1086), the thick-spacer MOSFET exhibits about +2 dB better performance than the thin-spacer MOSFET.

Simulations show that by moving to a 17 nm t2 thickness for the first dielectric spacer 908a of an asymmetric MOSFET compared to a 13 nm t1 thickness for the first dielectric spacer 808a results in the following device parameter improvements: C_{GS} (OFF state) is reduced by ˜15%; C_{GD} is reduced overall by ˜10%; f is improved by ˜5 GHz; f_{MAX} is improved by ˜10 GHz; BV_{DSS} is improved by 0.6V; and linear power is improved by ˜+2 dB at ˜45 dBc EVM and by ˜+0.5 dB at ˜40 dBc EVM.

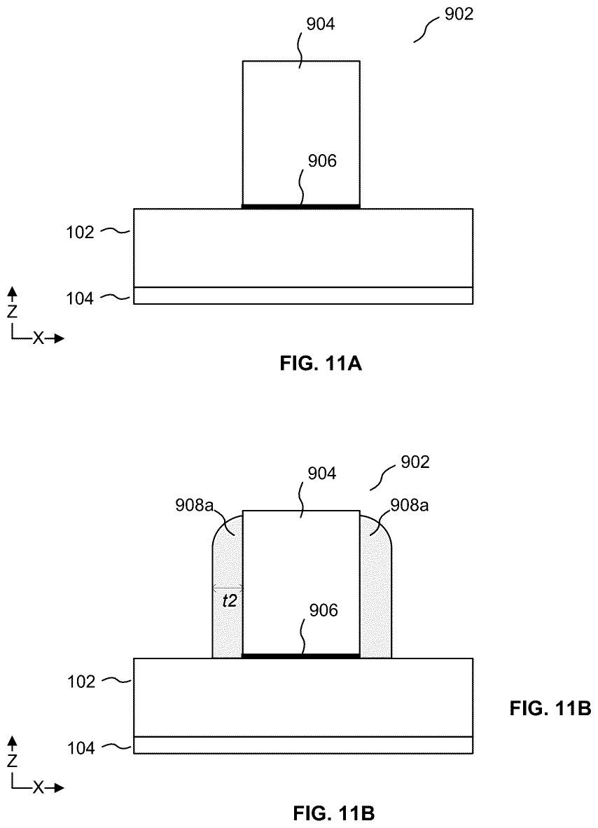

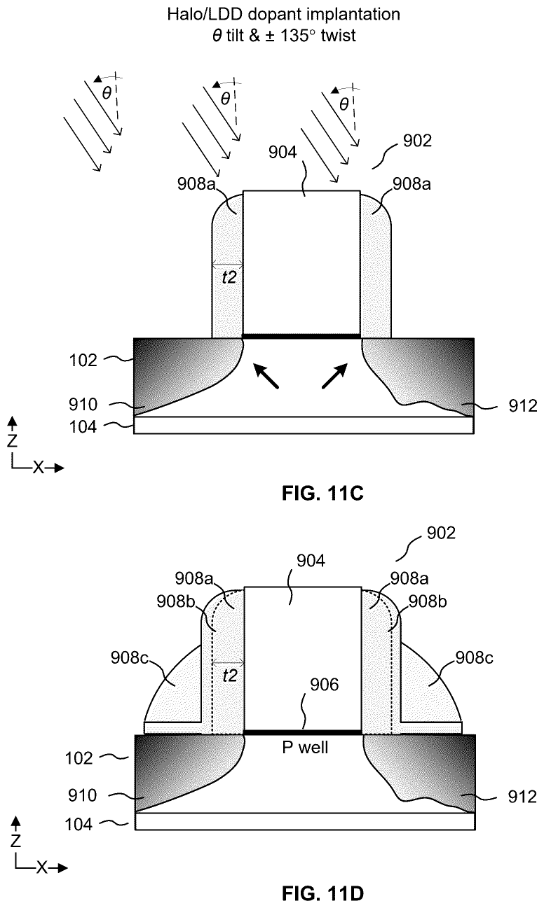

FIGS. 11A-11D are cross-sectional stylized views of example fabrication stages for the novel asymmetric MOSFET of FIG. 9.

FIG. 11A shows a portion of an active layer 102 formed on a BOX layer 104, which is in turn formed on top of a substrate (not shown). In some embodiments, the active layer 102 may be formed directly on top of a bulk Si substrate, thus omitting the BOX layer 104. The active layer 102 has been covered by an insulating gate oxide (GOX) layer 906, such as by thermal oxidation of the top portion of the active layer 102. The GOX layer 906 has been covered by a conductive layer 904, such as polysilicon or metal deposited by chemical-vapor deposition (CVD), and then the conductive layer 904 is photolithographically patterned and etched to form a gate structure 902.

FIG. 11B shows that first dielectric spacers 908a of thickness t2 have been formed along the sides of the gate structure 902, such as by low-temperature (i.e., thermal) oxidation (LTO) of SiO2) and etching.

FIG. 11C shows that a source-side implant region 910 and a drain-side implant region 912 are fabricated by asymmetric source-side angled implantation of suitable dopants to form halo and/or LDD regions, as described above (see, e.g., FIGS. 3A and 3B). By setting the thickness t2 of the first dielectric spacers 908a to a suitable value, the implant regions 910, 912 should not extend to any significant extent into the device channel beneath the lateral ledges of the conductive layer 904 within the gate structure edge 902.

FIG. 11D shows that a second dielectric spacer 908b (e.g., SiO₂) and a third dielectric spacer 908c (e.g., SiN) have been formed over the first dielectric spacer 908a, such as by deposition using plasma enhanced chemical vapor deposition (PECVD). The third dielectric spacer 908c may then be etched to a desired shape. In subsequent stages, source and drain regions may be formed within the active region 102 adjacent to respective implant regions 910, 912. Note that All of the associated processing steps for the spacers 908a-908c are self-aligned processing steps.

Note that not all steps that may be performed during the manufacture of MOSFETs within an IC are shown in FIGS. 11A-11D. Such steps may vary between IC foundries and may include (but are not limited to) substrate thinning, planarization, special implantations, annealing, formation of ohmic contacts, and formation of additional temporary or permanent structures (e.g., drift regions, substrate contacts, passivation layers, salicide blocks), etc.

While FIG. 9 and FIGS. 11A-11D show enhancement mode N-type MOSFETs, the teachings of this disclosure may be applied to enhancement mode P-type MOSFETs, depletion mode N-type MOSFETs, depletion mode P-type MOSFETs, and complementary metal-oxide-semiconductor (CMOS) FETs.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

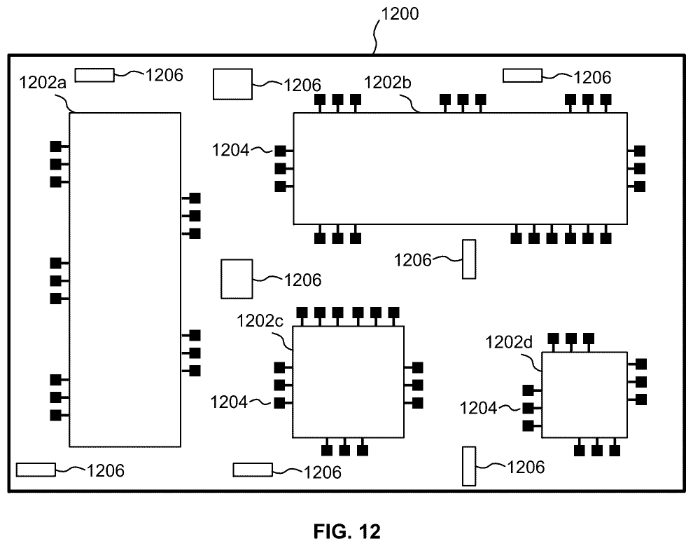

As one example of further integration of embodiments of the present invention with other components, FIG. 12 is a top plan view of a substrate 1200 that may be, for example, a printed circuit board or chip module substrate (e.g., a thin-film tile). In the illustrated example, the substrate 1200 includes multiple ICs 1202a-1202d having terminal pads 1204 which would be interconnected by conductive vias and/or traces on and/or within the substrate 1200 or on the opposite (back) surface of the substrate 1200 (to avoid clutter, the surface conductive traces are not shown and not all terminal pads are labelled). The ICs 1202a-1202d may embody, for example, signal switches, active and/or passive filters, amplifiers (including one or more LNAs), and other circuitry. For example, IC 1202b may incorporate one or more instances of a circuit that includes a non-90°, multi-twist implanted asymmetric MOSFET fabricated in accordance with the teachings of the present invention.

The substrate 1200 may also include one or more passive devices 1206 embedded in, formed on, and/or affixed to the substrate 1200. While shown as generic rectangles, the passive devices 1206 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 1200 to other passive devices 1206 and/or the individual ICs 1202a-1202d. The front or back surface of the substrate 1200 may be used as a location for the formation of other structures.

Embodiments of the present invention are useful in a wide variety of larger radio frequency (RF) circuits and systems for performing a range of functions, including (but not limited to) impedance matching circuits, RF power amplifiers, RF low-noise amplifiers (LNAs), phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

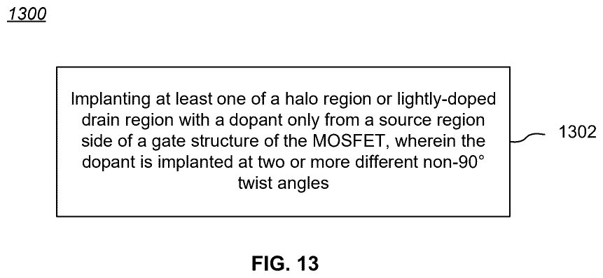

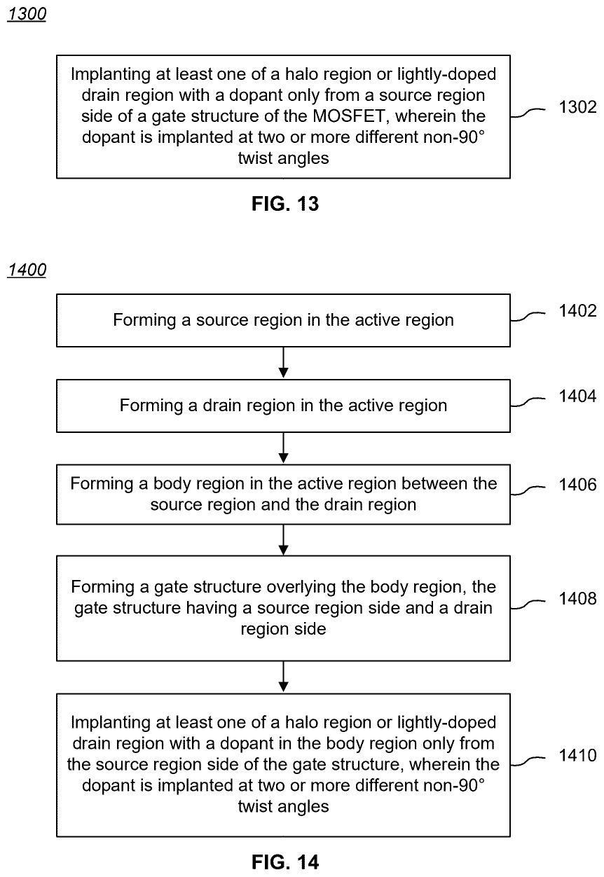

Another aspect of the invention includes methods for making high-performance asymmetric MOSFETs. For example, FIG. 13 is a process flow chart 1300 showing one method for making an asymmetric MOSFET. The method includes: implanting at least one of a halo region or lightly-doped drain region with a dopant only from a source region side of a gate structure of the MOSFET, wherein the dopant is implanted at two or more different non-90° twist angles (Block 1302).

As another example, FIG. 14 is a process flow chart 1400 showing one method for making an asymmetric MOSFET in and on an active region of an integrated circuit. The method includes: forming a source region in the active region (Block 1402); forming a drain region in the active region (Block 1404); forming a body region in the active region between the source region and the drain region (Block 1406); forming a gate structure overlying the body region, the gate structure having a source region side and a drain region side (Block 1408); and implanting at least one of a halo region or lightly-doped drain region with a dopant in the body region only from the source region side of the gate structure, wherein the dopant is implanted at two or more different non-90° twist angles (Block 1410).

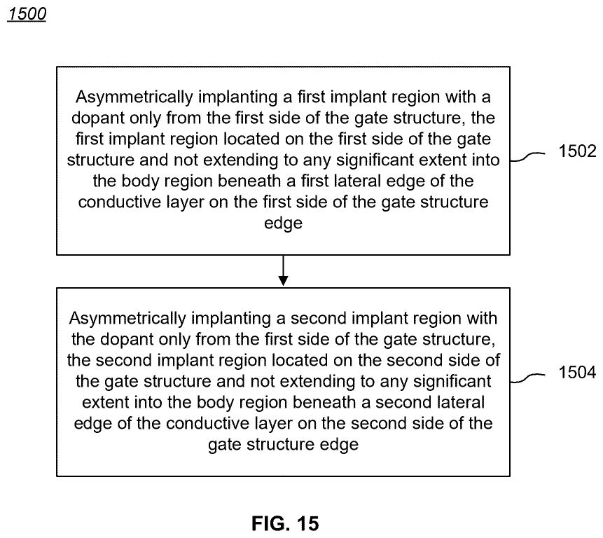

As yet another example, FIG. 15 is a process flow chart 1500 showing one method for making an asymmetric MOSFET having a gate structure overlying a body region, the gate structure including a conductive layer and having a first side and a second side. The method includes: asymmetrically implanting a first implant region with a dopant only from the first side of the gate structure, the first implant region located on the first side of the gate structure and not extending to any significant extent into the body region beneath a first lateral edge of the conductive layer on the first side of the gate structure edge (Block 1502); and asymmetrically implanting a second implant region with the dopant only from the first side of the gate structure, the second implant region located on the second side of the gate structure and not extending to any significant extent into the body region beneath a second lateral edge of the conductive layer on the second side of the gate structure edge (Block 1504).

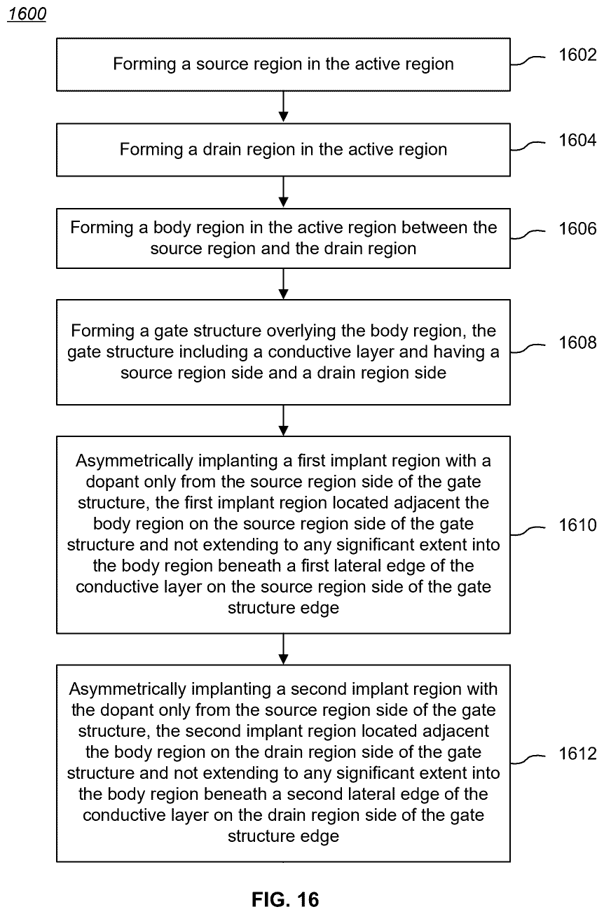

As still another example, FIG. 16 is a process flow chart 1600 showing one method for making an asymmetric MOSFET in and on an active region of an integrated circuit. The method includes: forming a source region in the active region (Block 1602); forming a drain region in the active region (Block 1604); forming a body region in the active region between the source region and the drain region (Block 1606); forming a gate structure overlying the body region, the gate structure including a conductive layer and having a source region side and a drain region side (Block 1608); asymmetrically implanting a first implant region with a dopant only from the source region side of the gate structure, the first implant region located adjacent the body region on the source region side of the gate structure and not extending to any significant extent into the body region beneath a first lateral edge of the conductive layer on the source region side of the gate structure edge (Block 1610); and asymmetrically implanting a second implant region with the dopant only from the source region side of the gate structure, the second implant region located adjacent the body region on the drain region side of the gate structure and not extending to any significant extent into the body region beneath a second lateral edge of the conductive layer on the drain region side of the gate structure edge (Block 1612).

Additional aspects of the above method may include one or more of the following: wherein implanting is at a first non-90° twist angle in a first quadrant with respect to the gate structure, and at a second non-90° twist angles in a second quadrant with respect to the gate structure; wherein implanting is at a first non-90° twist angle in a first range of about 0° to about 89° and at a second twist angle in a second range of from about 91° to about 180°; wherein implanting includes implanting a halo region with a dopant only from the source region side of the gate structure at a first tilt angle, and/or implanting a lightly-doped region with a dopant only from the source region side of the gate structure at a second tilt angle different from the first tilt angle; wherein the gate structure includes a central gate tab; wherein the gate structure includes two edge gate tabs, each located near a respective end of the gate structure; further including implanting the dopant at a 90° twist angle; and/or further including forming a first spacer on the first side of the gate structure and forming a second spacer on the second side of the gate structure, wherein the first and second spacers have a thickness selected to respectively prevent the first implant region from extending to any significant extent into the body region beneath the first lateral edge of the conductive layer and the second implant region from extending to any significant extent into the body region beneath the second lateral edge of the conductive layer.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as BiCMOS, LDMOS, BCD, GaAs HBT, GaN HEMT, GaAs pHEMT, MESFET, InP HBT, InP HEMT, FinFET, GAAFET, and SiC-based device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1.-28. (canceled)

29. An asymmetric metal-oxide-semiconductor field-effect transistor (MOSFET) including:
(a) a gate structure overlying a body region, the gate structure including a conductive layer and having a first side and a second side;
(b) a first implant region within the body region implanted with a dopant only from the first side of the gate structure, the first implant region located near the first side of the gate structure and not extending to any significant extent into the body region beneath the conductive layer; and
(c) a second implant region within the body region implanted with the dopant only from the first side of the gate structure, the second implant region located near the second side of the gate structure and not extending to any significant extent into the body region beneath the conductive layer.

30. The asymmetric MOSFET of claim 29, wherein the first implant region and second implant region include at least one of a halo region or lightly-doped drain region.

31. The asymmetric MOSFET of claim 29, further including a first spacer formed on the first side of the gate structure and a second spacer formed on the second side of the gate structure, wherein the first and second spacers have a thickness selected to respectively prevent the first and second implant regions from extending to any significant extent into the body region beneath the conductive layer.

32. The asymmetric MOSFET of claim 29, wherein the dopant is implanted at two or more different non-90° twist angles.

33. The asymmetric MOSFET of claim 32, wherein a first non-90° twist angle is in a first quadrant with respect to the gate structure, and a second non-90° twist angles is in a second quadrant with respect to the gate structure.

34. The asymmetric MOSFET of claim 32, wherein a first non-90° twist angle is in a first range of about 0° to about 89° and a second twist angle is in a second range of from about 91° to about 180°.

35. The asymmetric MOSFET of claim 32, wherein the dopant is also implanted at a 90° twist angle.

36. The asymmetric MOSFET of claim 29, wherein the gate structure includes a central gate tab.

37. The asymmetric MOSFET of claim 29, wherein the gate structure includes two edge gate tabs, each located near a respective end of the gate structure.

38. An asymmetric metal-oxide-semiconductor field-effect transistor (MOSFET) including:
(a) a source region;
(b) a drain region;
(c) a body region between the source region and the drain region;
(d) a gate structure overlying the body region, the gate structure including a conductive layer and having a source region side and a drain region side;
(e) a first implant region implanted with a dopant only from the source region side of the gate structure, the first implant region located near the source region side of the gate structure and not extending to any significant extent into the body region beneath the conductive layer; and
(f) a second implant region implanted with the dopant only from the source region side of the gate structure, the second implant region located near the drain region side of the gate structure and not extending to any significant extent into the body region beneath the conductive layer.

39. The asymmetric MOSFET of claim 38, wherein the first implant region and second implant region include at least one of a halo region or lightly-doped drain region.

40. The asymmetric MOSFET of claim 39, further including a first spacer formed on the first side of the gate structure and a second spacer formed on the second side of the gate structure, wherein the first and second spacers have a thickness selected to respectively prevent the first and second implant regions from extending to any significant extent into the body region beneath the conductive layer, and wherein the extent of implantation into the body beneath the conductive layer is different for the source region compared to the drain region because of the at least one of a halo region or lightly-doped drain region.

41. The asymmetric MOSFET of claim 38, further including a first spacer formed on the first side of the gate structure and a second spacer formed on the second side of the gate structure, wherein the first and second spacers have a thickness selected to respectively prevent the first and second implant regions from extending to any significant extent into the body region beneath the conductive layer.

42. The asymmetric MOSFET of claim 38, wherein the dopant is implanted at two or more different non-90° twist angles.

43. The asymmetric MOSFET of claim 42, wherein a first non-90° twist angle is in a first quadrant with respect to the gate structure, and a second non-90° twist angles is in a second quadrant with respect to the gate structure.

44. The asymmetric MOSFET of claim 42, wherein a first non-90° twist angle is in a first range of about 0° to about 89° and a second twist angle is in a second range of from about 91° to about 180°.

45. The asymmetric MOSFET of claim 42, wherein the dopant is also implanted at a 90° twist angle.

46. The asymmetric MOSFET of claim 38, wherein the gate structure includes a central gate tab.

47. The asymmetric MOSFET of claim 38, wherein the gate structure includes two edge gate tabs, each located near a respective end of the gate structure.

48.-61. (canceled)
